(19) United States
(12) Patent Application Publication
(10) Pub. No.: US 2010/0098518 A1
(43) Pub. Date: Apr. 22, 2010

(54) IN/OUT DOOR FOR A VACUUM CHAMBER

(75) Inventors: Hung T. Nguyen, Fremont, CA (US); George Tzeng, Sunnyvale, CA (US); Daniel I. Handjojo, Fremont, CA (US); Lawrence T. Nguyen, San Jose, CA (US); Jonathan Cerezo, Fremont, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/254,517

(22) Filed: Oct. 20, 2008

(51) Int. Cl. H01L 21/67

(52) U.S. Cl. 414/217; 414/805

(57) ABSTRACT

A load lock chamber sized for a large area substrate is provided. The load lock chamber includes a housing comprising a door and a body having at least two sealable ports, a movable door associated with at least one of the sealable ports, and a door actuation assembly coupled between the door and the housing. The door actuation assembly further includes a pair of first actuators coupled to the door for moving the door in a first direction, and a pair of second actuators for moving the door in a second direction that is orthogonal to the first direction.

### BACKGROUND OF THE INVENTION

1. Field of the Invention

Embodiments of the present invention relate to a selectively sealing an opening in a vacuum chamber. More particularly, to selectively sealing an opening in an evacuable transfer chamber.

2. Description of the Related Art

Semiconductor processes for large area substrates in the production of flat panel displays, solar cell arrays, and other electronic devices include processes such as deposition, etching, and testing, which are conventionally conducted in a vacuum processing chamber. To increase fabrication efficiency and/or lower production costs of the various end uses of the processed substrate, the large area substrates are currently about 2,200 mm× about 2,600 mm, and larger. The substrates are typically transferred into and out of the vacuum processing chamber through a transfer chamber that functions as an atmospheric/vacuum interface and is generally referred to as a load lock chamber. The load lock chamber provides a staged vacuum between atmospheric pressure and a pressure within the vacuum processing chamber. In some systems, the load lock chamber may be configured as a transfer interface between a queuing system at ambient pressure and the vacuum processing chamber providing for atmospheric to vacuum substrate exchange. Likewise, processed substrates may be transferred out of the vacuum processing chamber to atmospheric conditions through the load lock chamber.

The openings in the vacuum processing chambers and the load lock chambers are generally sized to receive at least one dimension (i.e. width or length) of the large area substrate to facilitate transfer of the substrate. The chamber openings are configured to be selectively opened and closed by a door to facilitate transfer of the substrate and vacuum sealing of the chamber. The operation of the door and effective sealing of the opening creates challenges to making and using of the chambers.

Therefore, there is a need for a vacuum chamber door that addresses these challenges.

### SUMMARY OF THE INVENTION

Embodiments of the present invention generally provide a door actuation assembly for a vacuum chamber sized for one or more large area substrates. In one embodiment, a vacuum chamber sized for a large area substrate is described. The vacuum chamber includes a housing comprising a body having at least one sealable port, a movable door coupled with the sealable port, and a door actuation assembly coupling the door and the housing. The door actuation assembly comprises first actuators coupled to the door for moving the door in a first direction, and second actuators for moving the door in a second direction, the second direction orthogonal to the first direction.

In another embodiment, a vacuum chamber sized for a large area substrate is described. The vacuum chamber includes a housing comprising a body having at least one sealable port, a movable door coupled with the sealable port, and a door actuation assembly coupling the door and the housing. The door actuation assembly comprises a pair of first actuators coupled to the door for moving the door in a first direction, a pair of linear guides coupled between opposing ends of the door and the housing, and a pair of second actuators coupled to the linear guides and movable with the door, for moving the door in a second direction orthogonal to the first direction.

In another embodiment, a method for selectively opening and closing a sealable port in a vacuum chamber for processing a large area substrate, wherein the vacuum chamber comprises a housing, a door associated with the sealable port, the door movably coupled to a linear guide on opposing ends thereof, and a moving mechanism having a pair of first actuators and a pair of second actuators is described. The method includes synchronously driving the first actuators coupled to the door, detecting a position of the door, returning a positional metric corresponding to the position of the door, and adjusting a moving speed of the first actuators based on the positional metric to ensure a longitudinal dimension of the door remains substantially orthogonal to a travel path of at least one of the linear guides coupled to the door.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A illustrates an isometric view of a load lock chamber according to one embodiment of the present invention.

FIG. 1B illustrates the load lock chamber shown in FIG. 1A in a more detail.

FIG. 2A illustrates the implementation of a horizontal actuator according to one implementation of the present invention.

FIG. 2B illustrates the operation of the horizontal actuator according to one embodiment of the present invention.

FIG. 2C illustrates the operation of the horizontal actuator according to another embodiment of the present invention.

FIG. 3 illustrates the operation of the load lock chamber according to one embodiment of the present invention.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein relate to a system and method for selectively sealing a chamber opening that is adapted to contain one or more large area substrates in low pressure conditions. In one embodiment, the chamber may be configured for transferring substrates to and from ambient atmosphere and a vacuum environment. Although some embodiments are exemplarily described for use in evacuable transfer chambers, such as load lock chambers or other chambers configured to provide an atmospheric/vacuum interface, some embodiments may be applicable for other chambers configured for other low pressure processes. Examples include, without limitations, processing chambers, testing chambers, deposition chambers, etch chambers, and thermal treatment chambers. Substrates, as described herein, include large area substrates made of glass, a polymer material, or other material suitable for forming electronic devices thereon, that are configured for flat panel display production, solar cell array production, and other electronic devices that may be formed on large area substrates. Examples include thin film transistors (TFT's ), organic light emitting diodes (OLED's ), and p-i-n junctions or other devices used in the manufacture of solar arrays and/or photovoltaic cells.

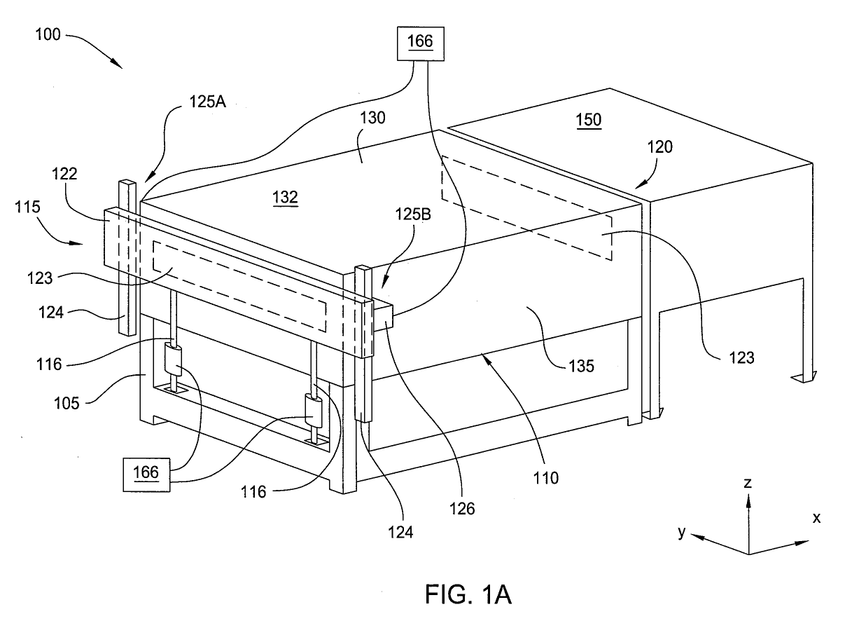

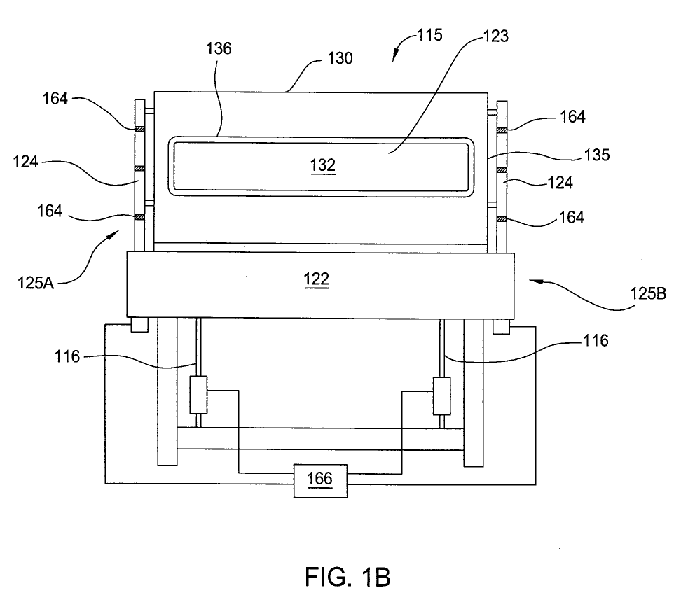

FIG. 1A is an isometric view illustrating one embodiment of a load lock chamber 100, which includes a sealable housing 110 disposed on a support frame 105. The housing 110 comprises a body 132, sidewalls 135, a bottom (not shown in this view), and a lid 130. The housing 110 has a first end 115 and a second end 120, each of which includes a sealable opening or port 123 (shown in phantom). At least one of the sealable ports 123 is selectively opened and closed by an in/out (I/O) door 122 (shown in a closed position in FIG. 1A and in an open position in FIG. 1B). The second end 120 may be a processing interface adapted to be coupled to and in selective communication with a vacuum processing chamber 150 configured for processing a large area substrate, such as a deposition chamber, an etch chamber, a testing chamber, and the like. The first end 115 may be an atmospheric interface, which may be an interface for an atmospheric robot, an atmospheric substrate queuing system, a conveyor device or other transfer device (not shown) disposed in a clean room.

The load lock chamber 100 includes a pair of first actuators 116 that are coupled to the I/O door 122 and the support frame 105. Each of the first actuators 116 are linear actuators that may be driven electrically, hydraulically, pneumatically, and combinations thereof. Examples of the first actuators 116 include an air cylinder, an electromechanically-operated cylinder, a hydraulic cylinder, a mechanically operated cylinder, and combinations of the above. The first actuators 116 are configured to synchronously raise and lower the I/O door 122 in at least a vertical (Z) direction. The first actuators 116 are also adapted to move the I/O door 122 in a substantially parallel orientation relative to the port 123. To facilitate parallel lifting and lowering of the I/O door 122, the I/O door 122 is coupled to two linear bearing blocks 124 respectively mounted at two ends 125A and 125B of the I/O door 122. The linear bearing blocks 124 are mounted to the sidewalls 135 of the load lock chamber 100. In one embodiment, the first actuators 116 may be horizontally spaced apart from each other to ensure uniform vertical (Z directional) movement of the I/O door 122.

In addition to vertical movement, the I/O door 122 is also adapted to move horizontally (X direction) facilitated by a pair of second actuators 126 respectively mounted on the two lateral ends 125A and 125B of the I/O door 122. The horizontal actuator blocks 126 are operable to move the I/O door 122 either toward the first end 115 for closing the sealable port 123, or away from the first end 115 for opening the sealable port 123. The second end 120 may also include another I/O door, another pair of linear bearing blocks, and another pair of first and second actuators, all of which are not shown.

As shown in FIG. 1B, the first end 115 of the housing 110 also includes an o-ring 136 that surrounds the sealable port 123. In the closed position, an inner surface of the I/O door 122 tightly contacts with the o-ring 136 to seal the port 123. In one embodiment, the o-ring 136 may be made of a plastic, resin, or other suitable materials adapted to ensure sealing of the port 123. As the o-ring 136 is mounted on the face of the housing 110, the o-ring 136 can be easily accessed for repair or replacement by moving the I/O door 122 to the open position, as shown in FIG. 1B.

In one embodiment, one or more position sensors 164 may also be coupled to each of the linear bearing blocks 124. The position sensors 164 are configured to transmit detection signals reflecting the respective positions of the lateral ends 125A and 125B of the I/O door 122 to a controller 166 coupled to each of the first actuators 116. In one embodiment, each sensor 164 may be a transducer, a Hall effect sensor, a proximity sensor, a linear encoder, such as encoder tape, and combinations thereof. In other embodiments, each of the first actuators 116 may include a position sensor (not shown), such as a rotary encoder or a shaft encoder adapted to provide a positional metric of each first actuator 116.

The controller 166 is also coupled to each of the second actuators 126. The controller 166 is adapted to receive a metric from each sensor 164 indicative of movement of the of the I/O door 122 relative to the bearing blocks 124. The controller 166 may process the movement information to control the directional movement and/or directional speed of one or both of the first actuators 116. The controller 166 is also adapted to receive positional information from the sensors 164 to actuate the second actuators 126 to facilitate horizontal movement of the I/O door 122. The lifting and lowering speed of each first actuator 116 can thereby be accurately controlled to prevent misalignment of the I/O door 122 relative to the bearing blocks 124 during lifting and lowering of the I/O door 122. The misalignment of the I/O door 122 relative to the bearing blocks 124 may occur if a single actuator is used to lift/lower the I/O door 122, in which case that actuator is disposed to be in contact with the center of the bottom of the I/O door 122. However, supporting the I/O door 122 with single actuator may cause a wobbling of the I/O door 122 over the course of the lifting/lowering thereof, especially when the I/O door 122 becomes much wider to accommodate the transfer of larger substrate. Such wobbling or misalignment might lead to jamming of linear bearing blocks 124.

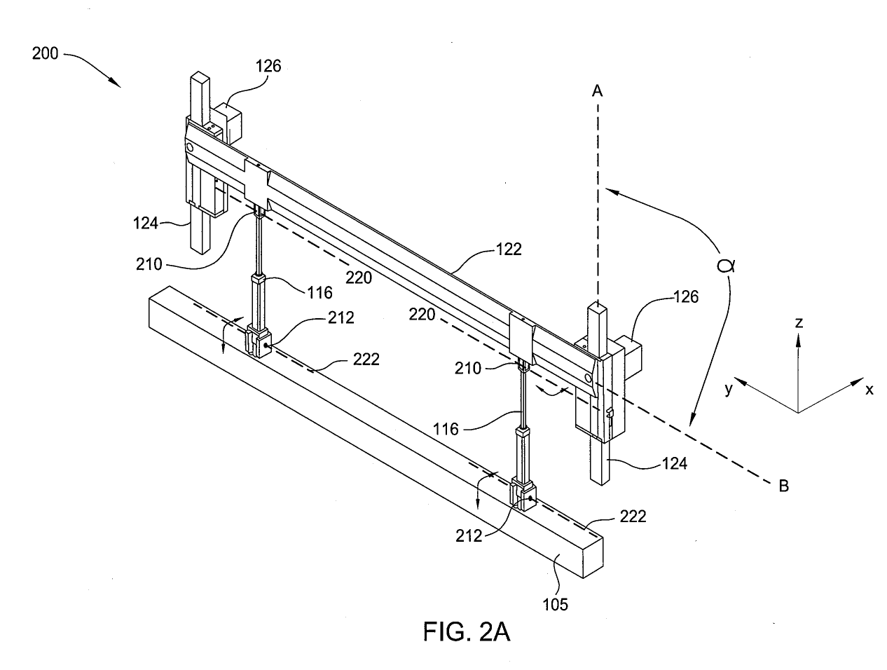

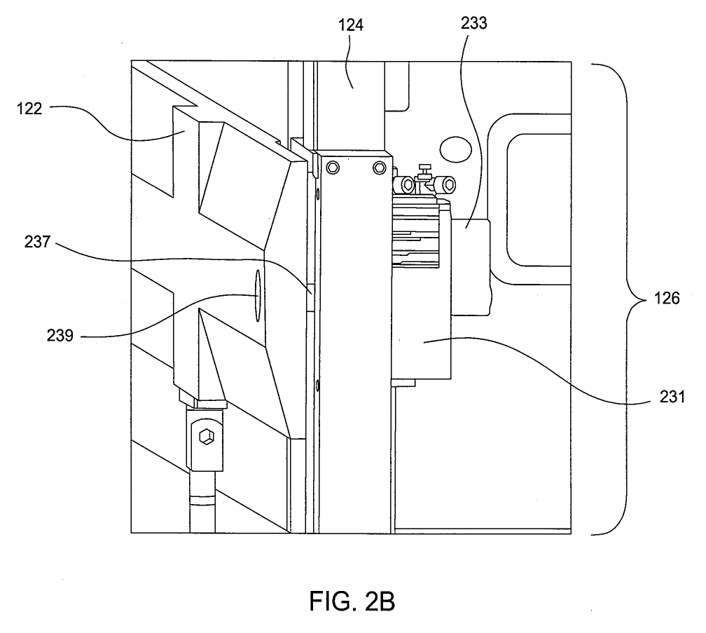

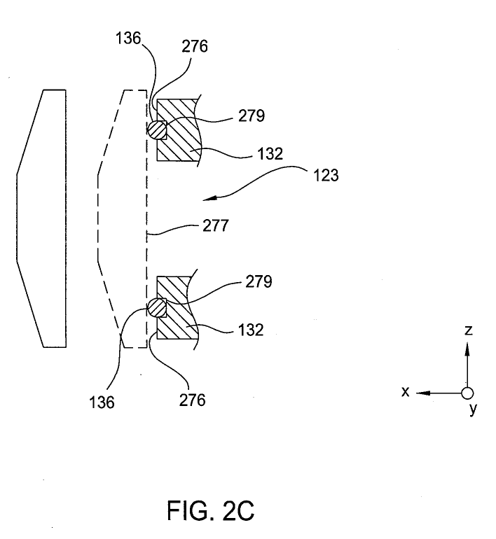

FIG. 2A is an isometric view illustrating one embodiment of an actuating mechanism 200 for an I/O door 122. The actuating mechanism 200 for the I/O door 122 comprises a pair of first actuators 116 adapted to drive vertical movements of the I/O door 122 along linear bearing blocks 124 and a pair of second actuators 126 providing horizontal movement of the I/O door 122, such as in the X direction or perpendicular to the plane of the I/O door 122. Each of the first actuators 116 has a first end coupled to the I/O door 122 at a first pivot link 210, and a second end coupled to the support frame 105 at a second pivot link 212. The first pivot link 210 may be rod-eye coupling or rod-clevis coupling adapted to swivel to prevent binding due to difference in speed and/or position between the first actuators 116. A rotational axis 220 of the first pivot links 210 and a rotational axis 222 of the second pivot links 212 are parallel to each other. The first and second pivot links 210 and 212 are thereby adapted to allow movements of the I/O door 122 in the horizontal direction (X direction) caused by the horizontal actuator blocks 126.

In one embodiment, the first actuators 116 are adapted to maintain the horizontal plane (X direction) of the I/O door 122 in an orthogonal relation relative to the linear bearing blocks 124. For example, the linear bearing blocks 124 include a longitudinal axis A and the I/O door 122 includes a longitudinal axis B. Based on positional information from the sensors 164, an angle α of about 90° may be maintained during lifting and lowering of the I/O door 122. This prevents misalignment of the I/O door 122 during lifting and lowering.

FIG. 2B is an enlarged view illustrating the construction of one horizontal actuator block 126. The horizontal actuator block 126 includes a bracket 231, a link shaft 233 and an actuator shaft 237. The link shaft 233 has a first end fixedly secured to the bracket 231, and a second end slidably passing through a hole (not shown) in the I/O door 122. The bracket 231 is thereby movable with the I/O door 122 along the linear bearing block 124. The bracket 231 provides support for the actuator shaft 237 that has one distal end 239 connected to the I/O door 122. In one embodiment, the distal end 239 is coupled to the I/O door 122 by a spherical bearing, which provides flexibility that allows the I/O door 122 to fully contact the o-ring 136. During operation, the course of the actuator shaft 237 causes horizontal movements of the I/O door 122 relative to the link shaft 233 to open and close the I/O door 122.

FIG. 2C is a schematic view illustrating horizontal (X directional) movements of the I/O door 122. In the closed position shown with the dotted lines, a contact surface 277 of the I/O door 122 is urged against a face 276 of the body 132 and tightly contacts the o-ring 136 surrounding the port 123. The o-ring 136 is secured in a groove 279 on the face 276. To open the port 123, the I/O door 122 is moved away from the face 276 in the X direction and out of contact with the o-ring 136. The vertical actuator blocks (not shown) can thereby operate to lower the I/O door 122 and open the port 123. Since the I/O door 122 can be moved away from the o-ring 136 when the I/O door 122 is to be lowered by the vertical actuator blocks, the o-ring 136 will not be damaged by the raising/lowering of the I/O door 122.

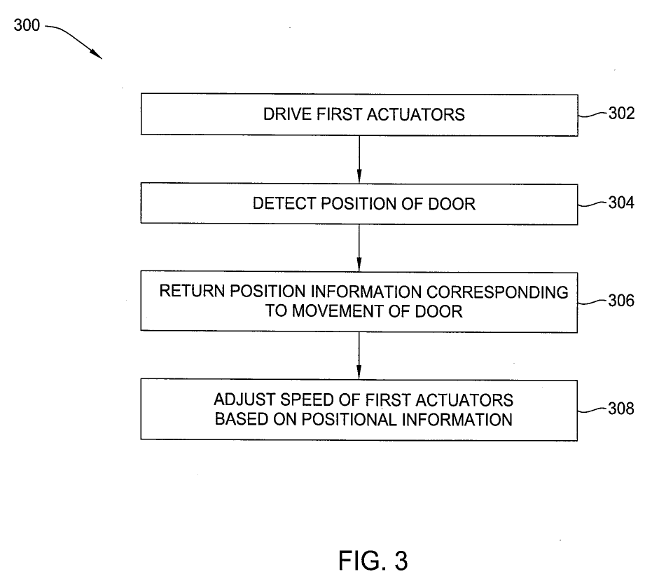

In conjunction with FIGS. 1A and 1B, FIG. 3 is a simplified flow chart illustrating an operation 300 of the load lock chamber 100 according to one embodiment of the present invention. In step 302, the first actuators 116 are driven by the controller 166 in a synchronous manner when driving the I/O door 122. In step 304, the sensors 164 are adapted to detect an exact position of the I/O door 122. In step 306, the sensors 164, after detecting the exact position of the I/O door 122, returns the position information corresponding to the detected position of the I/O door 122 to the controller 166. Thereafter, in step 308, the controller 166 adjusts the moving speed of the first actuators 116 on the basis of the returned position information. If the returned position information is indicative of any misalignment between the first actuators 116 the moving speed of each or both of the first actuators 116 will be adjusted. In doing so, the I/O door 122 could remain substantially parallel to the floor on which the load lock chamber 100 is placed.

While the foregoing is directed to embodiments of the present invention, other and further embodiments of the invention thus may be devised without departing from the basic scope thereof, and the scope thereof is determined by the claims that follow.

1. A vacuum chamber sized for a large area substrate, comprising:
a housing comprising a body having at least one sealable port;
a movable door coupled with the sealable port; and
a door actuation assembly coupling the door and the housing, the door actuation assembly comprising:
first actuators coupled to the door for moving the door in a first direction; and
second actuators for moving the door in a second direction, the second direction orthogonal to the first direction.

2. The apparatus of claim 1, wherein the first actuators comprise a pair of actuators disposed at positions corresponding to opposing ends of the door.

3. The apparatus of claim 1, wherein the moving mechanism further comprises a pair of linear guides coupled between opposing ends of the door and the housing.

4. The apparatus of claim 3, wherein the second actuators comprise a pair of actuators that are coupled to the linear guides and movable with the door.

5. The apparatus of claim 3 wherein each of the linear guides comprises at least one sensor coupled to a controller.

6. The apparatus of claim 5 wherein the controller is further coupled to the each of the first actuators so as to provide a synchronous movement between the first actuators.

7. The apparatus of claim 5 wherein the sensor is adapted to provide a positional metric of the door.

8. The apparatus of claim 1, wherein each of the first actuators are coupled to the door by a first pivoting link.

9. The apparatus of claim 1, wherein each of the first actuators are coupled to a frame of the housing by a second pivoting link.

10. The apparatus of claim 1, wherein the first and the second actuators are selected from the group consisting of an air cylinder, a hydraulic cylinder, an electromechanically-operated cylinder, and a mechanically-operated cylinder.

11. A vacuum chamber sized for a large area substrate, comprising:
a housing comprising a body having at least one sealable port;
a movable door coupled with the sealable port; and
a door actuation assembly coupling the door and the housing, the door actuation assembly comprising:
a pair of first actuators coupled to the door for moving the door in a first direction;
a pair of linear guides coupled between opposing ends of the door and the housing; and
a pair of second actuators coupled to the linear guides and movable with the door, for moving the door in a second direction orthogonal to the first direction.

12. The apparatus of claim 11, wherein the first actuators are disposed at positions corresponding to opposing ends of the door.

13. The apparatus of claim 11 wherein each of the linear guides comprises at least one sensor coupled to a controller.

14. The apparatus of claim 13 wherein the controller is further coupled to the each of the first actuators so as to provide a synchronous movement between the first actuators.

15. The apparatus of claim 13 wherein the sensor is adapted to provide a positional metric of the door.

16. The apparatus of claim 11 wherein each of the first actuators are coupled to the door by a first pivoting link.

17. The apparatus of claim 11 wherein each of the first actuators are coupled to a frame of the housing by a second pivoting link.

18. The apparatus of claim 11, wherein the first and the second actuators are selected from the group consisting of an air cylinder, a hydraulic cylinder, an electromechanically-operated cylinder, and a mechanically-operated cylinder.

19. A method for selectively opening and closing a sealable port in a vacuum chamber for processing a large area substrate, wherein the vacuum chamber comprises a housing, a door associated with the sealable port, the door movably coupled to a linear guide on opposing ends thereof, and a moving mechanism having a pair of first actuators and a pair of second actuators, the method comprising:
synchronously driving the first actuators coupled to the door;
detecting a position of the door;
returning a positional metric corresponding to the position of the door; and
adjusting a moving speed of the first actuators based on the positional metric to ensure a longitudinal dimension of the door remains substantially orthogonal to a travel path of at least one of the linear guides coupled to the door.

20. The method of claim 19 wherein the first actuators are disposed at positions corresponding to opposing ends of the door and inward of the linear guides.
